(19) United States
(12) Patent Application Publication
(10) Pub. No.: US 2010/0006886 A1
(43) Pub. Date: Jan. 14, 2010

(54) HIGH POWER LIGHT EMITTING DIODE CHIP PACKAGE CARRIER STRUCTURE

(75) Inventors: Chung-Chi Chang, Taipei City (TW); Hao-Jan Yu, Chungli City (TW)

Correspondence Address: BRILLIANT TECHNOLOGY CO., LTD., P.O.BOX 108-00403, Taipei, 106, omitted

(73) Assignee: BRILLIANT TECHNOLOGY CO., LTD., Aspire Park Lung-Tan (TW)

(21) Appl. No.: 12/170,449

(22) Filed: Jul. 10, 2008

(51) Int. Cl. H01L 33/00

(52) U.S. Cl. 257/99; 257/E33.001

(57) ABSTRACT

A high power LED (light-emitting diode) chip package carrier structure is disclosed and comprises a circuit board, a metal plate and a lid. The circuit board has a perforate groove for positioning a chip, and an electrode contact area formed at two sides or border of the perforate groove. The metal plate is positioned beneath the circuit board. The lid is positioned above the circuit board, and has a through groove with a width larger than the width of the perforate groove of the circuit board such that the electrode contact area can be exposed out in the through groove of the lid. Thus, the manufacturing process can be simplified and helpful to the mass production.

### BACKGROUND OF THE INVENTION

1. Field of the invention

The present invention relates to a high power LED (light-emitting diode) chip package carrier structure. More particularly, the present invention relates to a high power LED chip package carrier structure comprising an electrode contact area at two sides or border of a perforate groove of a circuit board, a metal plate and a lid positioned respectively on beneath and above the circuit board, and a through groove formed on the lid corresponding to the perforate groove of the circuit board. Thus, the manufacturing process of package carrier structure can be simplified, the electricity and heat of LED chip package can be separated, and this present invention is helpful to packaging quality and mass production.

2. Description of Related Art

Along with the rapidly advancement of technology, many high-tech products have excellent functions for improving convenience of either at work or daily life. The high-tech products provide outstanding processing speed and convenience to the users to enjoy more comfortable living environment. The chip package is very commonly used in the high-tech products for upgrading the functions. Conventionally, COB (chip on board) is one of the package method for the integrate circuit by gluing and packaging a naked chip on a printed circuit substrate, and also combine with the three basic processes, namely, gluing chip (chip bonding), connecting conducting wire (wire bonding) and applying packaging technology (molding). Thus, the packaging and testing steps during the manufacturing process can effectively be transferred to the circuit board assembling process. This packaging technology is actually a miniaturized surface mounting technology. Besides, the conducting wire is employed for electrically connecting the contact point of the chip with the contact point on the circuit board or the substrate, and finally the package technology is carried out.

Referring to FIG. 9, for instance, taking a conventional COB structure of light emitting diode (LED) as an example. A packaged light emitting diode A is disposed on welding pad B1 of a metal circuit substrate B (copper substrate or aluminum substrate), and two terminals Al extended from the two sides of the packaged light emitting diode A are respectively electrically connected to two welding pads B2 of a printed circuit on the metal circuit substrate B. However, the conventional structure described above has the following defects.

1. The welding pad B1 of the metal circuit substrate B can only mount one light emitting diode A independently, therefore the brightness will be affected and limited. In order to increase the brightness, a plurality of light emitting diodes A needs be installed on the metal circuit substrate B. Thus, the fabrication cost is increased and also increased the space occupation, which cannot meet the present trend for miniaturization of the product.

2. The heat generated from the light emitting diode A during emitting light will accumulate on the metal circuit substrate B through the welding pad B1. Because the metal plate B4 is positioned beneath the welding pad B1 by the thermal conductive dielectric B3 and not adhered directly to the light emitting diode A, thus the dissipating speed of the heat generated from the light emitting diode A is slower and the heat resistance is accordingly increased and shortens the life and emitting efficiency of the light emitting diode A thereof.

Therefore, how to overcome the above defect is the target for the manufacturers in the field.

### SUMMARY OF THE INVENTION

The object of the present invention is to provide a high power LED chip package carrier structure and a method for fabricating.

According to the object of the present invention, a circuit board comprises at least one perforate groove for positioning the chip, and the electrode contact area formed at the two sides or the border of perforate groove for electrically connecting with the printed circuit. The electrode contact area comprises a positive electrode and a negative electrode, and an insulated block area is formed there-between. A metal plate and a lid are jointed to the circuit board respectively on the lower side and the upper side, and at least one through groove on the lid can correspond to the perforate groove of the circuit board for exposing the electrode contact area. Thus, the fabrication of the high power LED chip package carrier structure can be simplified and the fabrication cost can be reduced.

According to another object of the present invention, the chip positioned in the perforate groove of the circuit board is attached to the surface of the metal plate. Thus, the heat generated from the chip can be rapidly dissipated to the metal plate. Thus, the heat and the electricity can be separated. Accordingly, the life and light emitting efficiency of the chip can be maintained, and the stability and reliability of the electrode conjunction will not be affected.

According to third object of the present invention, the perforate groove of the circuit board can position at least one chip, and the conducting wires extended from the chips is electrical connecting to the positive electrode and the negative electrode on one electrode contact area. Thus, the space occupation of metal circuit substrate and the quantity of packaged light emitting diode can be substantially reduced, and the cost can also be reduced. Thus, the overall height and thickness can be reduced to meet the present trend of miniaturization of product.

### BRIEF DESCRIPTION OF THE DRAWING

FIG. 1 is an exteriority view of a high power LED chip package carrier structure according to a preferred embodiment of the present invention.

FIG. 2 is an exploded view of the high power LED chip package carrier structure according to a preferred embodiment of the present invention.

FIG. 3 is a sectional side view of the high power LED chip package carrier structure according to a preferred embodiment of the present invention.

FIG. 4 is a flowchart of the process of fabricating the high power LED chip package carrier structure according to a preferred embodiment of the present invention.

FIG. 5 is a frontal view of the high power LED chip package carrier structure according to a preferred embodiment of the present invention.

FIG. 6 is a sectional side view of a finished package of the present invention according to a preferred embodiment.

FIG. 7 is a frontal view of the high power LED chip package carrier structure according to another preferred embodiment of the present invention.

FIG. 8 is a sectional side view of the high power LED chip package carrier structure according to another preferred embodiment of the present invention.

FIG. 9 is a sectional side view of a conventional high power LED.

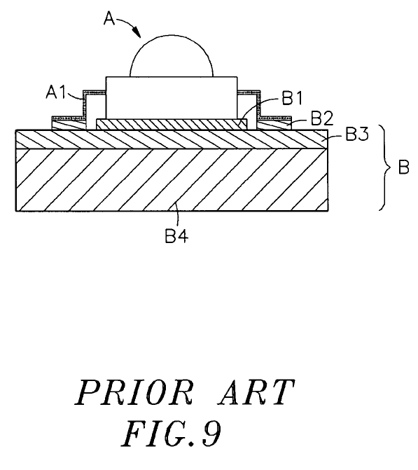

### DETAIL DESCRIPTION OF THE INVENTION

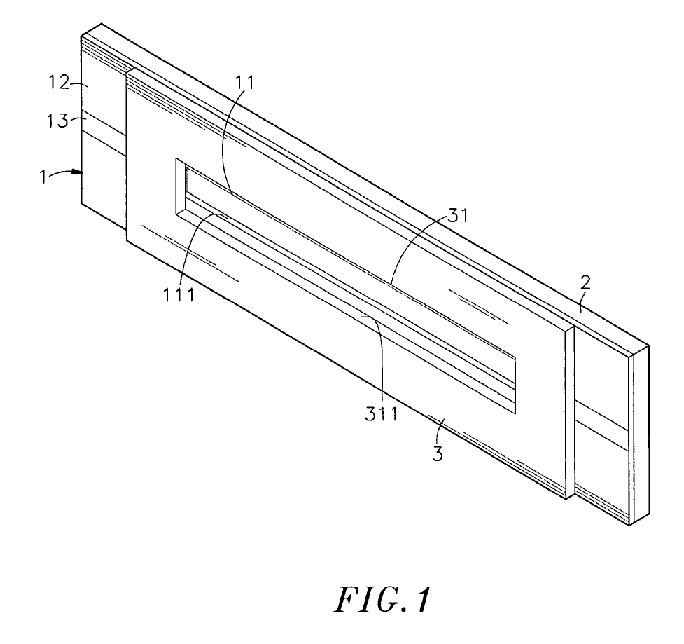

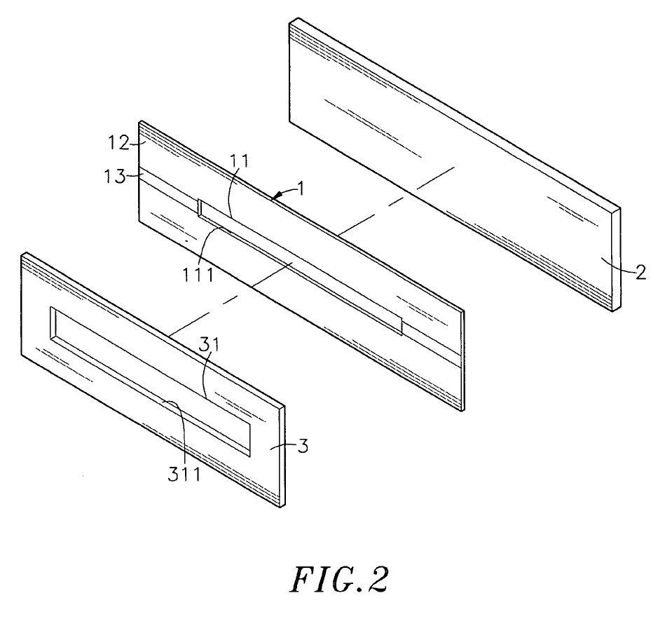

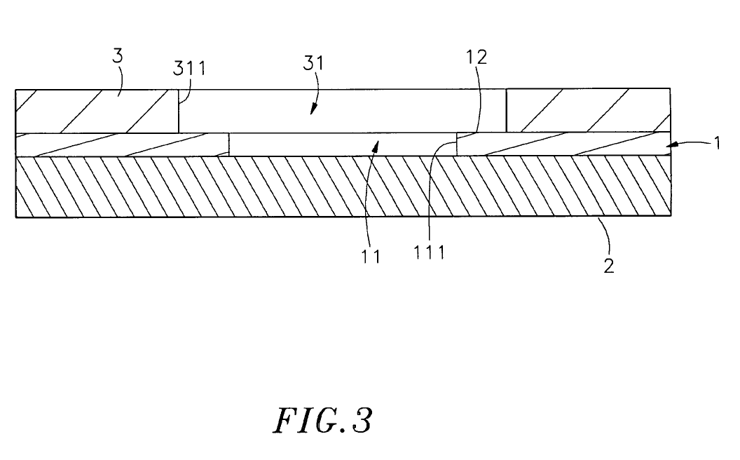

Referring to FIGS. 1, 2 and 3, the present invention comprises a circuit board 1, a metal plate 2 and a lid 3.

The circuit board 1 comprises a long perforate groove 11 at a central region thereof, an electrode contact area 12 at the two sides of the long perforate groove 11 for electrically connecting to a printed circuit board, and a insulated block area 13 formed between the electrode contact area 12. The perforate groove 11 has a light guide surface 111 vertically positioned at an inner sidewall or with a declining angle. The electrode contact area 12 includes a positive electrode and a negative electrode.

The metal plate 2 is jointed to the lower portion of the circuit board 1, and the size of the metal plate 2 is fit to the circuit board 1.

The lid 3 comprises a through groove 31 at a central region, and the width of the through groove 31 is larger than the width of the perforate groove 11. The through groove 31 has a light guide surface 311 vertically positioned on an inner sidewall or with a declining angle.

To comprise the above structure, the metal plate 2 and the lid 3 are respectively jointed to the lower portion and the upper portion of the circuit board 1 to enable the through groove 31 of the lid 3 to be correspondingly positioned to the perforate groove 11 of the circuit board 1 such that the electrode contact area 12 on the two sides of the perforate groove 11 can be exposed out in the through groove 31 of the lid 3.

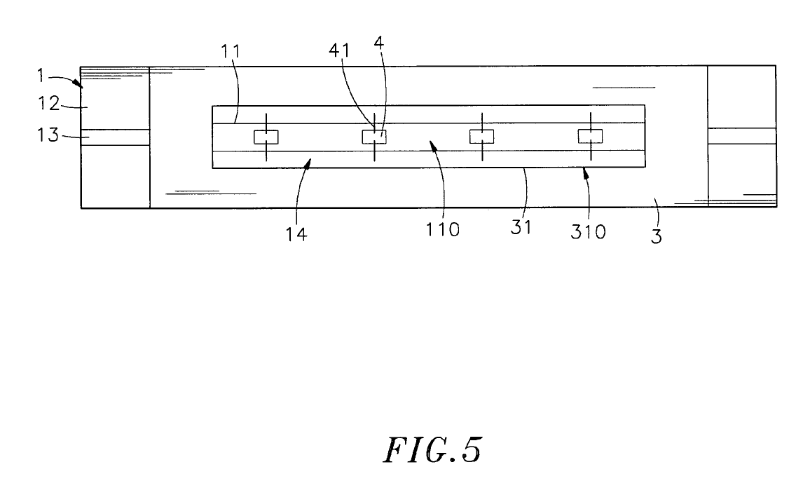

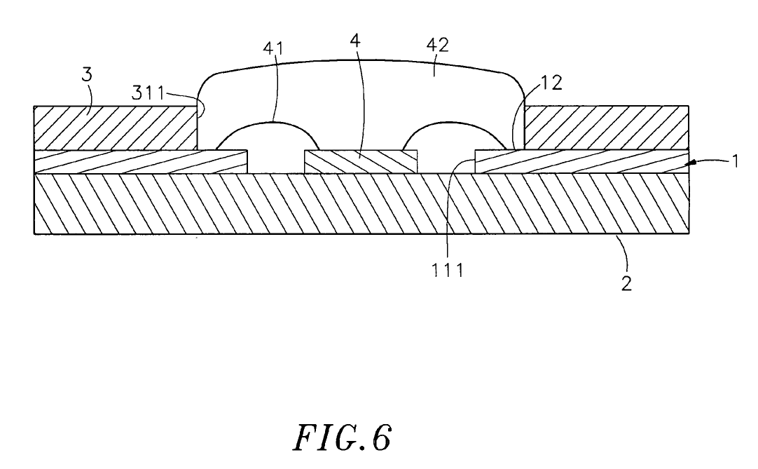

To apply the embodiment, the metal plate 2 and the lid 3 are respectively positioned on the lower portion and the upper portion of the circuit board 1. Because the through groove 31 of the lid 3 is correspondingly positioned to the perforate groove 11 of the circuit board 1 and the width of the through groove 31 is larger than the width of the perforate groove 11, thus, the electrode contact area 12 can be exposed out in the through groove 31 of the lid 3 to enable a conducting wire 41 of a chip 4 respectively connect to the positive electrode and the negative electrode on the electrode contact area 12 of the circuit board 1, as shown in FIGS. 5 and 6.

Furthermore, at least one or a plurality of chip 4 can be positioned in the perforate groove 11 of the circuit board 1, as shown in FIGS. 5 and 6, and the bottom surface of the chip 4 is attached to the surface of the metal plate 2. Such that, the heat generated by the chip 4 can be rapidly transferred to the metal plate 2 via the bottom surface of the chip 4 and the heat accumulation on the chip 4 can be reduced for extending the life and light emitting efficiency of the chip 4. The stability and the reliability of the electrical transmission of the electrode contact area 12 are not adversely affected. Thus, the heat and the electricity can be substantially separated.

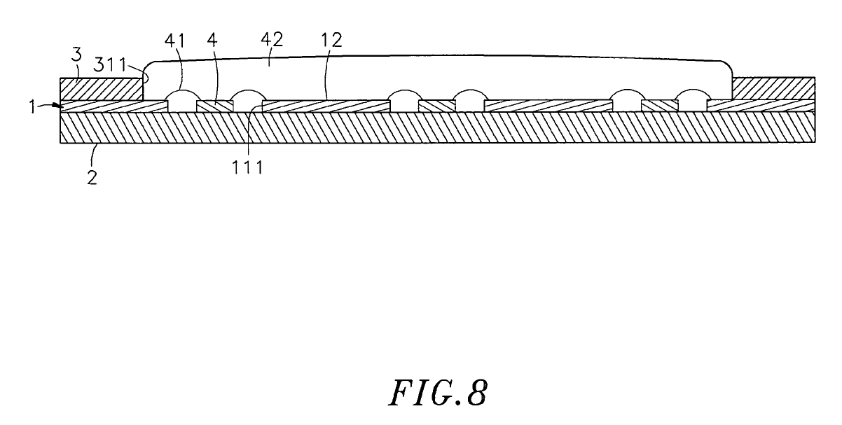

Furthermore, there is at least one or a plurality of perforate groove 11 formed at a central region of the circuit plate 1, as shown in FIG. 8, and at least one or a plurality of chip 4 can be positioned in the perforate groove 11. After the bottom surface of the chip 4 is attached to the metal plate 2, the conducting wire 41 of the chip 4 is respectively connected to the positive electrode and the negative electrode of the electrode contact area 12 of the circuit board 1. Thus, the high power LED package carrier structure with the COB (chip on board) package technology is completed. Accordingly, by sharing one main body, the space occupation on the metallic circuit substrate may be effectively reduced and thereby reduce the cost and the overall height can also be reduced. Furthermore, the fabrication process can also be substantially simplified and the structure can be stabilized to meet the present trend of miniaturization of the product.

Furthermore, the light guide surfaces 111 and 311 are positioned on the inner sidewall of the perforate groove 11 of the circuit board 1 and the through groove 31 of the lid 3, which is vertically positioned or with a declining angle to provide the chip 4 a good reflection angle while emitting the light. Thus, the light emitting from the chip 4 can be effectively collected and projected outwards. Accordingly, the utilization of light efficiency can be effectively increased. Besides, for increasing the overall brightness of the white light LED, the light guide surface 111 of the perforate groove 11 of the circuit board 1 is applied as the border to border the fluorescent powder for reducing the consumption of the fluorescent powder. However, the white light LED is not intended for limiting the scope of the present invention. Additionally, the light guide surface 311 of the lid 3 can stop the molding glue 42 from flowing out during the fabrication process, and also provides a better outline after the molding glue 42 solidifies. Thus, the emitting light from the chip 4 can evenly project outwards with a better effect and quality.

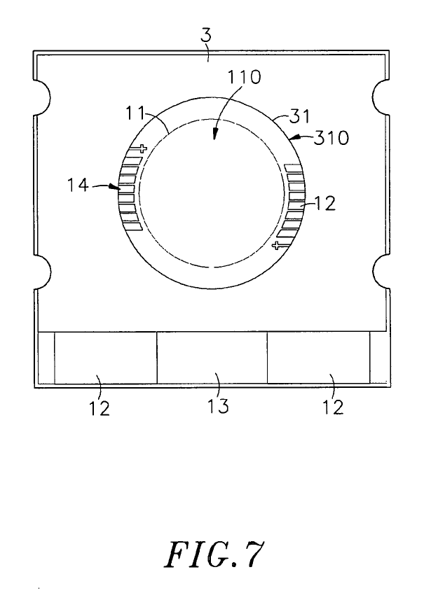

The metal plate 2 can be made of copper, aluminum, graphite, ceramics, or other thermal conductive materials. The lid 3 can be made of metal, ceramics, and high molecular polymer material. The circuit board 1, the metal plate 2 and the lid 3 can comprise an elongated, spherical, oval, rectangular or other shapes. The perforate groove 11 of the circuit board 1 and the through groove 31 of the lid 3 can also be formed in an elongated, spherical, oval, rectangular or other shapes as shown in FIG. 7, as long the electrode contact area 12 on the side or border of the perforate groove 11 can be exposed out in the through groove 31 of the lid 3. The above description is merely for illustrating the embodiments of the present invention, and they are not intended to limit the scope of the present invention.

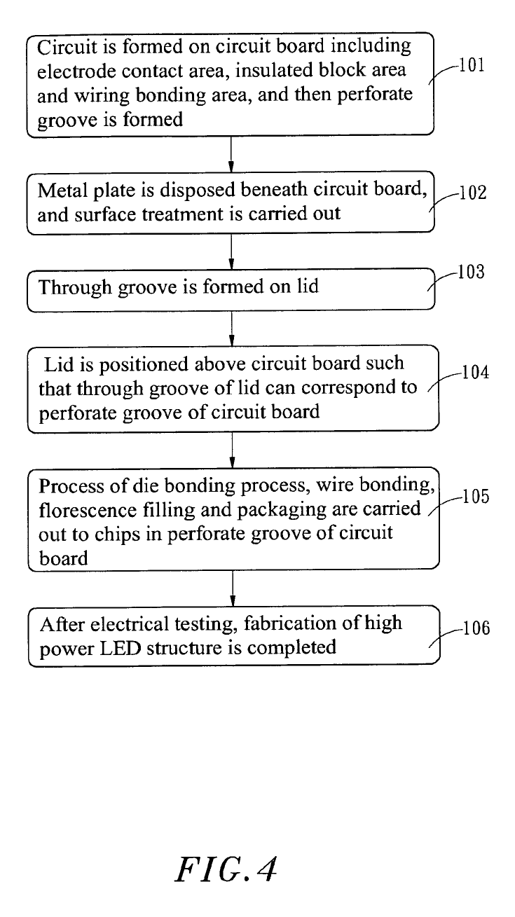

Referring to FIGS. 4, 5 and 6, the process of applying the embodiment of the present invention is described as follows.

At step 101, a circuit is formed on a circuit board 1 including an electrode contact area 12, an insulated block area 13 and a wiring bonding area 14, and then a perforate groove 11 is formed.

At step 102, a metal plate 2 is disposed beneath the circuit board 1, and then to carry out the surface treatment.

At step 103, a through groove 31 is formed on a lid 3.

At step 104, the lid 3 is positioned above the circuit board 1 such that the through groove 31 of the lid 3 can correspond to the perforate groove 11 of the circuit board 1.

At step 105, the process of die bonding process, wire bonding, florescence filling and packaging are carried out to chips 4 in the perforate groove 11 of the circuit board 1.

At step 106, after the electrical testing, the fabrication of the high power LED structure is completed.

Another process of applying the embodiment of the present invention is described as follows.

At step 201, a circuit is formed on a circuit board 1 including an electrode contact area 12, a insulated block area 13 and a wiring bonding area 14, and then a perforate groove 11 is formed on the circuit board 1, in the meantime, a through groove 31 is formed on a lid 3, and the surface treatment to a metal plate 2 is simultaneously carried out.

At step 202, the metal plate 2 is disposed beneath the circuit board 1, and the lid 3 is positioned above the circuit board 1 such that the through groove 31 of the lid 3 can correspond to the perforate groove 11 of the circuit board 1.

At step 203, chips 4 are positioned in the perforate groove 11 of the circuit board 1, and then the process of die bonding, wire bonding, florescence filling and packaging are carried out.

At step 204, after the electrical testing, the fabrication of the high power LED structure is completed.

According to the above description, a circuit is formed on the circuit board 1 including an electrode contact area 12, an insulated block area 13 and a wiring bonding area 14. Then, the perforate groove 11 is formed on the circuit board 1 by machining or chemical etching. The perforate groove 11 comprises a die bonding area 110 for positioning at least one or a plurality of chip 4. After positioning the metal plate 2 beneath the circuit board 1, the surface treatment to the metal plate 2 exposed out of the perforate groove 11 of the circuit board 1 can be processed by an electroplating or sputtering process. Furthermore, the through groove 31 formed on the lid 3 is processing by machining or chemical etching process, and then the lid 3 is positioned above the circuit board 1 such that the through groove 31 of the lid 3 can correspond to the perforate groove 11 of the circuit board 1.

Furthermore, the conducting wire 41 of the chip 4 is electrically connected to the wire bonding area 14 of the circuit board 1 to further connect to the positive electrode and the negative electrode. A seal area 310 is formed on the through groove 31 of the lid 3 corresponding to the perforate groove 11 of the circuit board 1, and a molding glue 42 is used to seal the seal area 310 and the surface of the chip 4. Finally, after the electrical testing, the fabrication of the high power LED structure is completed. Thus, the fabrication process is simple and helpful to the mass production. Thus, the quality control can be easily implemented and the fabrication cost can be effectively reduced.

The steps 101 to 104 described above including forming a circuit on the circuit board 1 including an electrode contact area 12, a insulated block area 13 and a wiring bonding area 14; forming the perforate groove 11; positioning the metal plate 2 beneath the circuit board 1 and carrying out the surface treatment; forming a through groove 31 on the lid 3; and positioning the lid 3 above the circuit board 1 such that the through groove 31 of the lid 3 can correspond to the perforate groove 11 of the circuit board 1, is used for merely demonstrating the embodiment of the present invention, it is not intended for limiting the scope of the present invention. The steps sequence can be changed, for example, the circuit board 1, the metal plate 2 and the lid 3 may be simultaneously processed, and the metallic plate 2 and the lid 3 respectively may be positioned beneath and above the circuit board 1. Therefore, any literally or structural changes in the method, the steps and the process order can achieve the same result, and shall be construed to be within the scope of the present invention.

The advantages of the high power LED chip package carrier structure and the manufacturing method thereof has at least the following advantages.

1. The circuit board 1 comprises the perforate groove 11 for positioning the chip 4, and the electrode contact area 12 is formed at the two sides or border of the perforate groove 11. Then, the metal plate 2 and the lid 3 are positioned beneath and above the circuit board 1 such that the through groove 31 of the lid 3 can correspond to the perforate groove 11 of the circuit board 1. Thus, the high power LED chip package carrier structure is completed. Thus, the process is simplified and helpful to the mass production. Thus, quality control can be implemented easily and the fabrication cost can be reduced.

2. The chip 4 positioned in the perforate groove 11 of the circuit board 1 is attached to the surface of the metal plate 2. The heat generated during emitting light from the chip 4 can be rapidly transferred to the metal plate 2, and therefore the heat will not be accumulated on the chip 4. Accordingly, the life and light emitting efficiency of the chip 4 can be prolonged without adversely affecting the stability and reliability of the electrode conjunction, and thereby separating the heat and the electricity.

3. There is at least one or a plurality of chip 4 positioned in the perforate groove 11, and the conducting wire 41 extended from the chip 4 is connected to the wiring bonding area 14 and further respectively connected to the positive electrode and the negative electrode on the electrode contact area 12 of the circuit board 1. By sharing one main body, the space occupation on the metallic circuit substrate can be reduced and the cost and the overall height of the product can be reduced. Thus, the process can be simplified and the structure can be stabilized to meet the current trend miniaturization of the product.

4. By applying the fabrication process to the white light LED, the light guide surface 111 of the perforate groove 11 of the circuit board 1 is used as the border to border the fluorescent powder for reducing the consumption of the fluorescent powder. However, this is not intended for limiting the scope of the present invention. Such that, the light guide surface 111 can provide a good reflection angle to the chip 4 while emitting light, and the light can be collected and project outwards. Accordingly, the light utilization efficiency can be increased, and the overall brightness of the white light LED can be increased.

5. The light guide surface 311 of the lid 3 can stop the molding glue 42 from flowing out during the fabrication process, as well as enables to form a better outline after the molding glue 42 solidifies. Thus, the light from the chip 4 can evenly project outwards with a better effect and quality.

While the invention has been described in conjunction with a specific best mode, it is to be understood that many alternatives, modification, and variations will be apparent to those skilled in the art in light of the foregoing description. Accordingly, it is intended to embrace all such alternatives, modification, and variations in which fall within the spirit and scope of the included claims. All matters set forth herein or shown in the accompanying drawings are to be interpreted in an illustrative and non-limiting sense.

What the invention claimed is:

1. A high power LED (light-emitting diode) chip package carrier structure, comprising:
a circuit board, having a perforate groove for positioning a chip, and an electrode contact area formed at two sides or border of said perforate groove for connecting to printed circuit
a metal plate, positioned beneath said circuit board; and
a lid, positioned above said circuit board, having a through groove with a width larger than the width of said perforate groove of said circuit board, wherein said through groove is corresponding to said perforate groove of said circuit board for exposing said electrode contact area out in said through groove of said lid.

2. The high power LED chip package carrier structure according to claim 1, wherein said chip can be at least one or multiple and is attached to said metal plate.

3. The high power LED chip package carrier structure according to claim 1, wherein said perforate groove comprises a light guide surface vertically positioned at an inner sidewall or with a declining angle.

4. The high power LED chip package carrier structure according to claim 1, wherein said perforate groove formed on said circuit board is processing by a machine or chemical etching process.

5. The high power LED chip package carrier structure according to claim 1, wherein said perforate groove comprises a die bonding area for positioning said chip can be at least one or multiple.

6. The high power LED chip package carrier structure according to claim 1, wherein said circuit board further comprises an electrode contact area and insulated block area and a wire bonding area.

7. The high power LED chip package carrier structure according to claim 6, wherein said insulated block area is formed between said electrode contact area.

8. The high power LED chip package carrier structure according to claim 1, wherein said electrode contact area comprises a positive electrode and a negative electrode for connecting to said conducting wire extended from said chip.

9. The high power LED chip package carrier structure according to claim 1, wherein said metal plate is selected from the group consisting copper, aluminum, graphite, ceramics and other thermal conductive materials.

10. The high power LED chip package carrier structure according to claim 1, wherein said metallic plate is integrally formed with said circuit board before a surface treatment, and said surface treatment includes an electroplating or a sputtering process.

11. The high power LED chip package carrier structure according to claim 1, wherein said through groove on said lid comprises a light guide surface vertically positioned on an inner sidewall or with a declining angle.

12. The high power LED chip package carrier structure according to claim 1, wherein said through groove on said lid is formed by machining or chemical etching process.

13. The high power LED chip package carrier structure according to claim 1, wherein a seal area is formed at said through groove of said lid corresponding to said perforate groove of said circuit board.

14. The high power LED chip package carrier structure according to claim 1, wherein said lid is selected from the group consisting metal, ceramics, and high molecular polymer compound.

15. The high power LED chip package carrier structure according to claim 1, wherein said circuit board, said metal plate and said lid can form an elongated, spherical oval or rectangular shape.

16. The high power LED chip package carrier structure according to claim 1, wherein said perforate groove of the circuit board and said through groove of the lid can form an elongated, spherical oval or rectangular shape.
